(19) United States
(12) Patent Application Publication
(10) Pub. No.: US 2009/0072382 A1
(43) Pub. Date: Mar. 19, 2009

(54) MICROELECTRONIC PACKAGE AND METHOD OF FORMING SAME

(76) Inventor: John S. Guzek, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/857,418

(22) Filed: Sep. 18, 2007

(51) Int. Cl. H01L 23/36; H01L 21/56

(52) U.S. Cl. 257/712; 257/783; 438/118; 257/E21.502; 257/E23.101

(57) ABSTRACT

A microelectronic package includes a carrier (110, 210, 410, 1110) having a first surface (111, 211, 411, 1111) and an opposing second surface (112, 212, 412, 1112), an adhesive layer (120, 220, 221, 520, 1220, 1221) at the first surface of the carrier, a die (130, 230, 231, 530, 531, 1230, 1231) attached to the first surface of the carrier by the adhesive layer, an encapsulation material (140, 240, 640, 1340) at the first surface of the carrier and at least partially surrounding the die and the adhesive layer, and a build-up layer (150, 250, 750, 1450) adjacent to the encapsulation material, wherein the die and the build-up layer are in direct physical contact with each other. In one embodiment the carrier is a heat spreader having a first surface and a second surface the second surface being a top surface of the microelectronic package.

### FIELD OF THE INVENTION

The disclosed embodiments of the invention relate generally to packages for microelectronic devices, and relate more particularly to Bumpless Build-Up Layer (BBUL) packages for microelectronic devices.

### BACKGROUND OF THE INVENTION

Microelectronic packaging technology, including methods to mechanically and electrically attach a silicon die to a substrate or other carrier, continues to be refined and improved over time. A packaging technology that is currently in wide use is known as flip-chip (or C4—controlled collapse chip connect) technology, in which a die is connected to its package using a set of C4 solder bumps. Flip-chip technology, however, is characterized by a number of troubling issues, many of which grow increasingly problematic as device scaling continues.

Bumpless Build-Up Layer (BBUL) technology is one approach to a packaging architecture that addresses several of these issues. Among other advantages, BBUL eliminates the need for assembly, eliminates the flip-chip interconnect (resulting in higher performance and higher reliability), reduces stress on low-k inter-layer dielectric (ILD) due to die-to-substrate coefficient of thermal expansion (CTE) mismatch, and dramatically reduces package inductance (through elimination of core and flip-chip interconnect) for improved input/output (I/O) and power delivery performance.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic package according to an embodiment of the invention;

FIG. 2 is a cross-sectional view of a microelectronic package according to another embodiment of the invention;

FIG. 3 is a flowchart illustrating a method of forming a microelectronic package according to an embodiment of the invention;

FIGS. 4-9 are cross-sectional views of a microelectronic package at various particular points in a manufacturing process according to an embodiment of the invention;

FIG. 10 is a flowchart illustrating a method of forming a microelectronic package according to an embodiment of the invention; and

FIGS. 11-15 are cross-sectional views of a microelectronic package at various particular points in a manufacturing process according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,”, “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a carrier having a first surface and an opposing second surface, an adhesive layer at the first surface of the carrier, a die attached to the first surface of the carrier by the adhesive layer, an encapsulation material at the first surface of the carrier and at least partially surrounding the die and the adhesive layer, and a build-up layer adjacent to the encapsulation material, wherein the die and the build-up layer are in direct physical contact with each other.

In the same or another embodiment, a microelectronic package comprises a heat spreader having a first surface and a second surface (wherein the second surface is a top surface of the microelectronic package), a die attached to the first surface of the heat spreader, an encapsulation material at the first surface of the heat spreader, the encapsulation material at least partially surrounding the die, and a build-up layer physically contacting the encapsulation material and physically and electrically contacting the die.

Embodiments of the invention may address certain current and anticipated future issues with the overall scalability of flip-chip packaging in order to meet future CPU and Chipset performance and cost requirements. Embodiments of the invention may enhance BBUL technology in a variety of ways, including, for example, by enhancing thermal performance through the addition of an integrated heat spreader (IHS) and/or thin-die thin-thermal interface material (TIM) (often abbreviated as TDTT) technology; by enhancing electrical performance through the integration of passive components (e.g., capacitors, resistors, and the like); improving manufacturing throughput through the use of injection-molded encapsulant; and improving design scalability through the integration of multiple die and patterning technologies that provide finer circuit formation design rules.

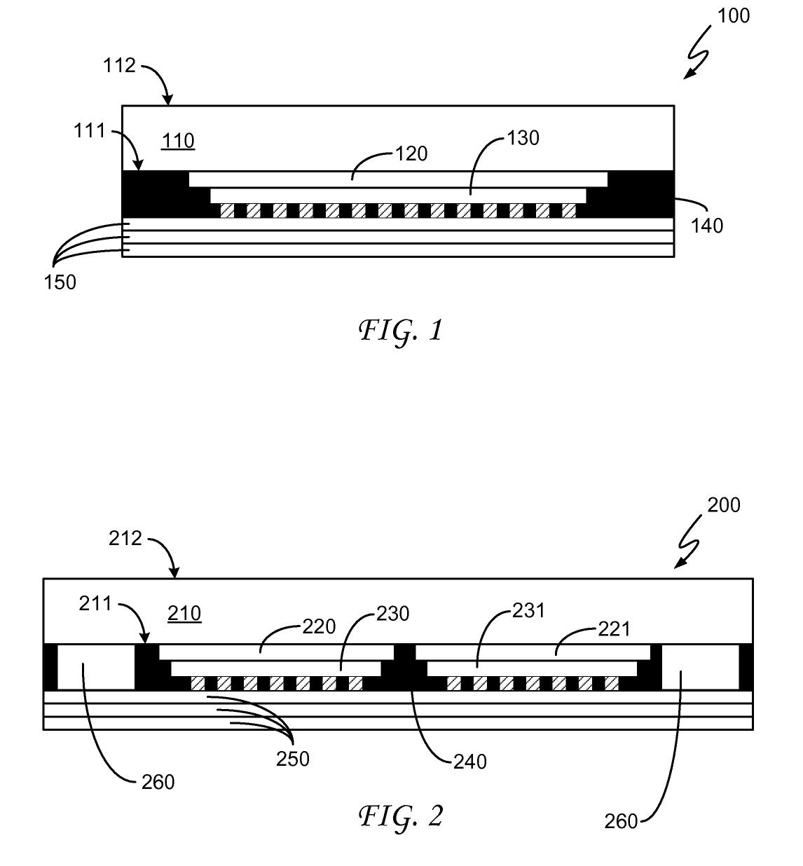

Referring now to the drawings, FIG. 1 is a cross-sectional view of a microelectronic package 100 according to an embodiment of the invention. As illustrated in FIG. 1, microelectronic package 100 comprises a carrier 110 having a surface 111 and an opposing surface 112, an adhesive layer 120 at surface 111 of carrier 110, and a die 130 attached to surface 111 of carrier 110 by adhesive layer 120. In at least one embodiment, surface 112 is a top surface of microelectronic package 100. As an example, die 130 can be a silicon die or the like having a thickness of approximately 400 micrometers. As another example, die 130 can be a silicon die or the like that has been thinned to a thickness of approximately 150 micrometers or even to approximately 75 micrometers. Other thicknesses are, of course, also possible.

Microelectronic package 100 further comprises an encapsulation material 140 at surface 111 of carrier 110 that at least partially surrounds die 130 and adhesive layer 120 and still further comprises at least one build-up layer 150 adjacent to encapsulation material 140. As is the case with all BBUL packages, die 130 and build-up layer 150 are in direct physical contact with each other. In at least one embodiment, microelectronic package 100 comprises multiple build-up layers 150, including metal and dielectric layers (connected with vias or the like) that provide connectivity to the die (power, ground, input/output (IO), etc.).

In one embodiment, carrier 110 comprises a thermally conductive material and/or an electrically conducting material. In a particular embodiment, carrier 110 comprises a sheet made of copper or another material that is both thermally and electrically conductive and that serves as a carrier for building up microelectronic package 100. In the same or another embodiment, carrier 110 is also a heat spreader for microelectronic package 100.

In one embodiment, adhesive layer 120 comprises a thermal interface material (TIM) such as a thermal grease, an elastomer pad, a phase change material, a polymer gel, a solder material, and the like. In another embodiment, adhesive layer 120 comprises a removable adhesive film. As an example, adhesive layer 120 in this embodiment may be a film made of biaxially-oriented polyethylene terephthalate (boPET) polyester film (commercially available, for example, from DuPont Teijin Films under the names Melinex® and Mylar®) or the like that disintegrates or loses its adhesive properties in response to certain stimuli, as will be further explained below. Such a film could be applied so as to cover all of (or substantially all of), or just a portion of, surface 111 of carrier 110. It should be understood that in the latter embodiment adhesive layer 120 may not, after a certain point in a manufacturing process, be present in microelectronic package 100 (notwithstanding its presence in FIG. 1). Such manufacturing details, with their resulting structural ramifications, will be discussed in more detail below.

In one embodiment a plurality of dies are present within a microelectronic package. In the same or another embodiment, one or more passive components are present within a microelectronic package. FIG. 2 is a cross-sectional view of a microelectronic package 200 according to this embodiment of the invention. As illustrated in FIG. 2, microelectronic package 200 comprises a carrier 210 having a surface 211 and an opposing surface 212, adhesive layers 220 and 221 at surface 211, dies 230 and 231 attached to surface 211 by, respectively, adhesive layers 220 and 221, an encapsulation material 240 at surface 211 that at least partially surrounds dies 230 and 231 and adhesive layers 220 and 221, and at least one build-up layer 250 adjacent to encapsulation material 240. As an example, carrier 210, surface 211, surface 212, adhesive layers 220 and 221, dies 230 and 231, encapsulation material 240, and build-up layer 250 can be similar to, respectively, carrier 110, surface 111, surface 112, adhesive layer 120, die 130, encapsulation material 140, and build-up layer 150.

Although FIG. 2 depicts just two dies (die 230 and die 231), in other embodiments microelectronic package 200 (or another microelectronic package) could include more than two dies. Microelectronic package 200 further comprises at least one passive component 260, as is also illustrated in FIG. 2. As illustrated, passive component 260, which may be a capacitor, a resistor, an inductor, or the like, may be attached to surface 211 and be at least partially surrounded by encapsulation material 240. In addition to, or in place of, passive component 260, microelectronic package 200 (or another microelectronic package) may comprise, for example, an integrated thin-film capacitor or the like (not shown) in build-up layer 250.

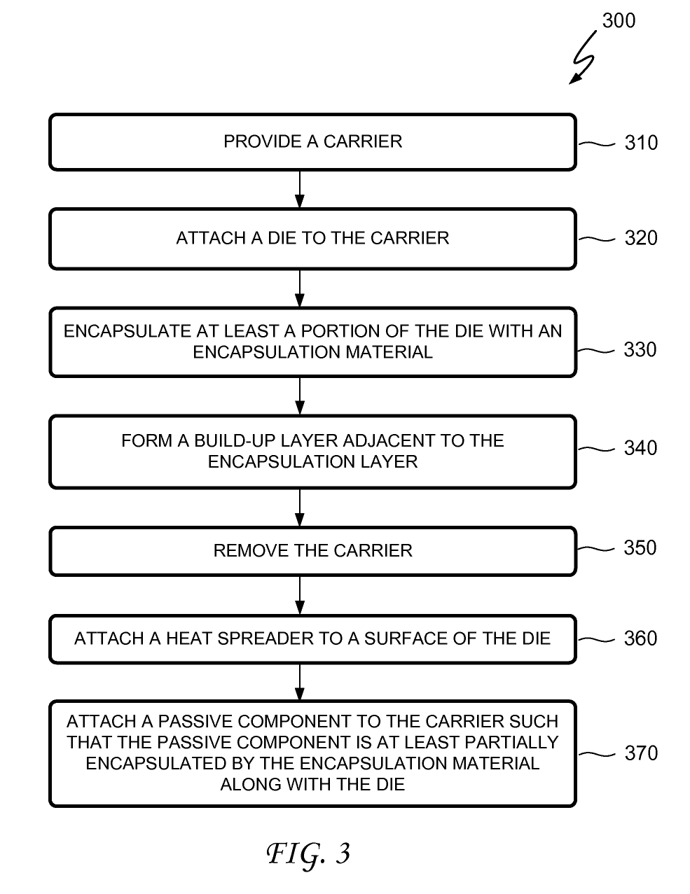

FIG. 3 is a flowchart illustrating a method 300 of forming a microelectronic package according to an embodiment of the invention. A step 310 of method 300 is to provide a carrier. As an example, the carrier can be similar to carrier 110 that is shown in FIG. 1. As another example, the carrier can be similar to a carrier 410 that is first shown in FIG. 4, which is a cross-sectional view of a microelectronic package 400 at a particular point in a manufacturing process according to an embodiment of the invention. In one embodiment, FIG. 4 depicts microelectronic package 400 as it may appear following the performance of step 310. As illustrated in FIG. 4, carrier 410 has a surface 411 and an opposing surface 412.

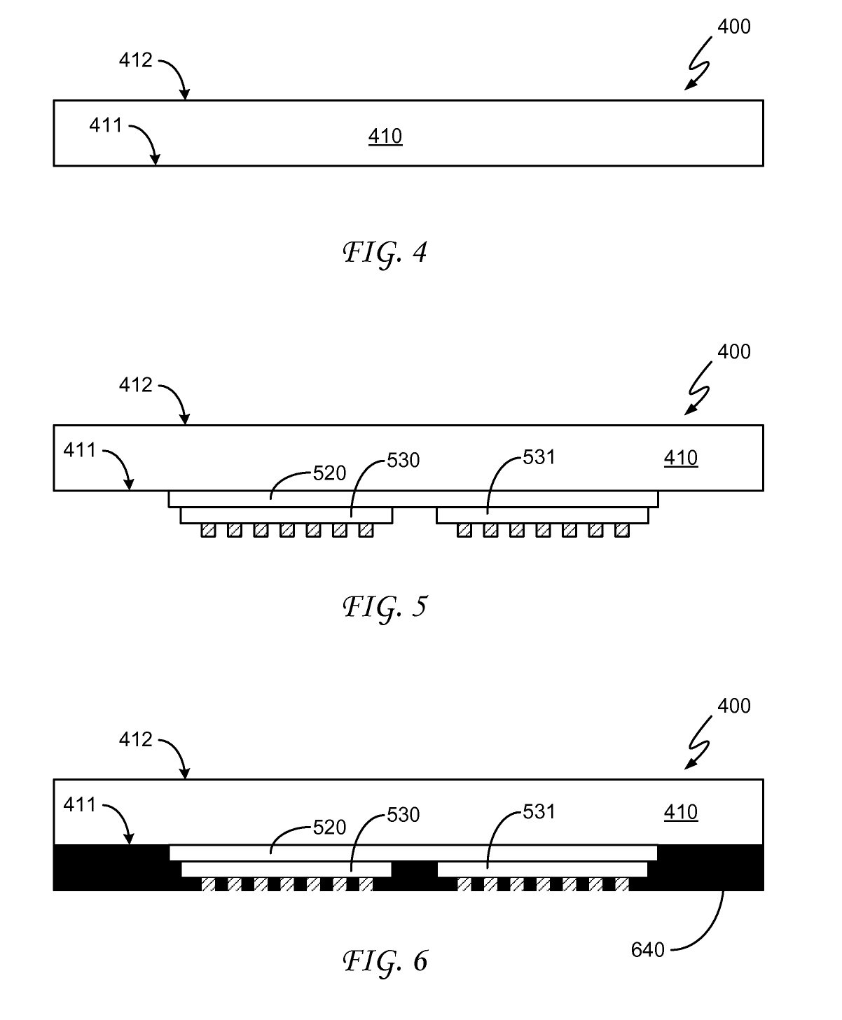

A step 320 of method 300 is to attach a die to the carrier. As an example, the die can be similar to die 130 that is shown in FIG. 1. As another example, the die can be similar to a die 530 that is first shown in FIG. 5, which is a cross-sectional view of microelectronic package 400 at a particular point in a manufacturing process according to an embodiment of the invention. In one embodiment, FIG. 5 depicts microelectronic package 400 as it may appear following the performance of step 320.

In one embodiment, step 320 comprises applying an adhesive film either to the die or the carrier (or to both the die and the carrier) and then bringing the die and the carrier into physical contact with each other such that an adhesive bond is formed between the die and the carrier. As an example, the adhesive film can be a film that disintegrates or may otherwise be weakened enough that it falls away or is released from the die and/or the carrier to which it was attached. As illustrated in FIG. 5, die 530 has been attached to carrier 410 with an adhesive film 520, which can be similar to the adhesive film mentioned above in connection with step 320. FIG. 5 also depicts a die 531, which may be similar to die 530, thus illustrating that two (or more than two) dies can be processed simultaneously in a single package. These may later be singulated in order to increase manufacturing throughput. In a different embodiment, dies may be processed one at a time.

A step 330 of method 300 is to encapsulate at least a portion of the die with an encapsulation material. As an example, the encapsulation material can be similar to encapsulation material 140 that is shown in FIG. 1. As another example, the encapsulation material can be similar to an encapsulation material 640 that is first shown in FIG. 6, which is a cross-sectional view of microelectronic package 400 at a particular point in a manufacturing process according to an embodiment of the invention. In one embodiment, FIG. 6 depicts microelectronic package 400 as it may appear following the performance of step 330.

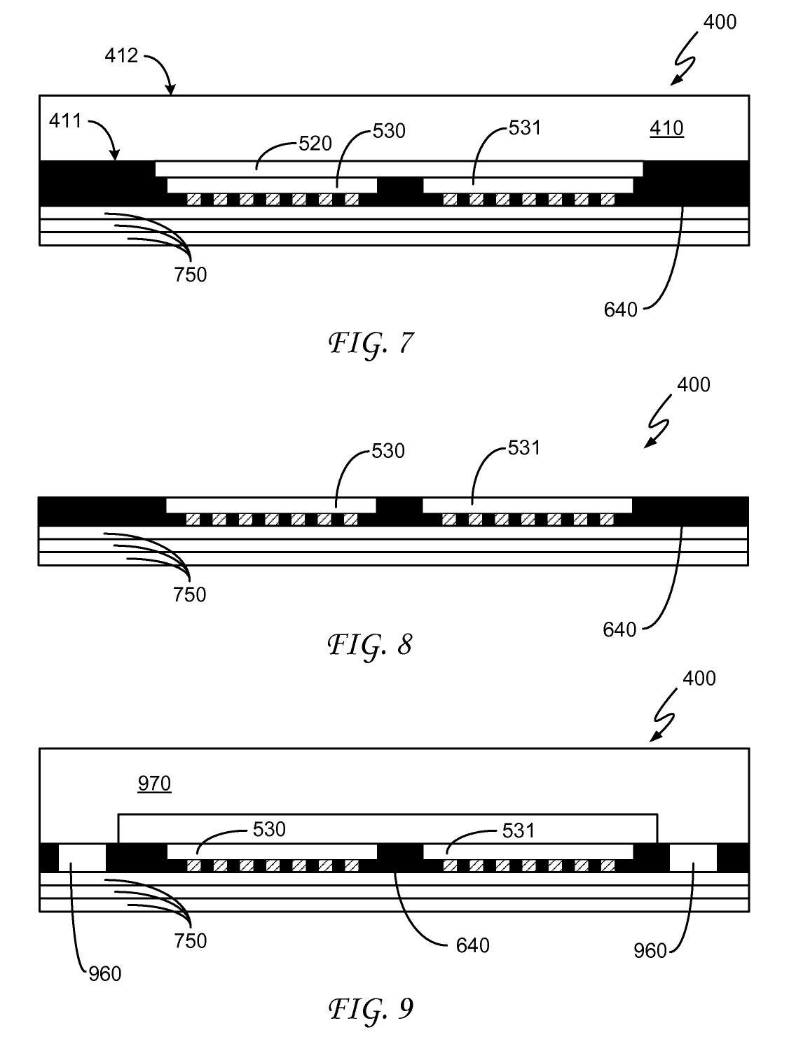

A step 340 of method 300 is to form at least one build-up layer adjacent to the encapsulation material. As an example, the build-up layer can be similar to build-up layer 150 that is shown in FIG. 1. As another example, the build-up layer can be similar to a build-up layer 750 that is first shown in FIG. 7, which is a cross-sectional view of microelectronic package 400 at a particular point in a manufacturing process according to an embodiment of the invention. In one embodiment, FIG. 7 depicts microelectronic package 400 as it may appear following the performance of step 340. In one embodiment, step 340 comprises forming an integrated thin-film capacitor (not shown) in the build-up layer as part of the build-up process.

A step 350 of method 300 is to remove the carrier, thus forming an exposed-die package. Accordingly, method 300 may be used in embodiments where the end product does not require a heat spreader. Alternatively, this process flow could be used along with a post-singulation IHS attachment if there are advantages to manufacturing the product in this manner.

In one embodiment, step 350 comprises removing the adhesive bond between the die and the carrier. As an example, removing the adhesive bond may comprise applying thermal radiation, ultraviolet radiation, or the like to the adhesive bond until the adhesive bond is released. FIG. 8, which is a cross-sectional view of microelectronic package 400 at a particular point in a manufacturing process according to an embodiment of the invention, depicts microelectronic package 400 as it may appear following the performance of step 350. It should be understood that the adhesive film creating the adhesive bond would be very thin relative to the die, so the actual gap between the die backside and encapsulation material would be small. This gap should be easily filled by the next level of thermal interface material. One could, however, include an optional planarization step in the process flow in order to ensure planarity of the two surfaces.

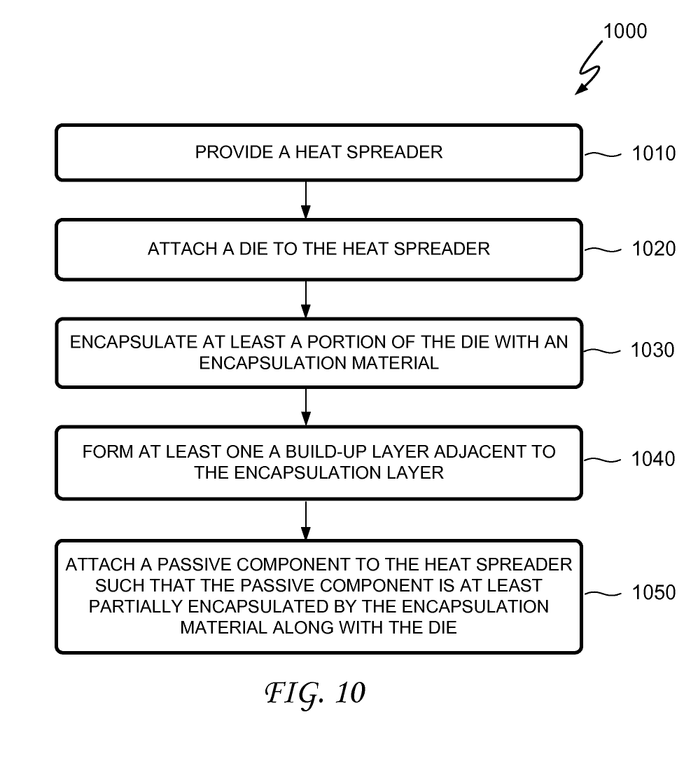

A step 360 of method 300 is to attach a heat spreader to a surface of the die, if a heat spreader is needed or desired. In one embodiment, the heat spreader would be attached using a TIM (solder, polymer, etc.) on the backside of the die and using a non-conductive adhesive between the top of the encapsulation material and the heat spreader in the area outside the die. As an example, the heat spreader can be similar to a heat spreader 970 that is first shown in FIG. 9, which is a cross-sectional view of a microelectronic package 400 at a particular point in a manufacturing process according to an embodiment of the invention. In one embodiment, step 360 may be omitted, such that microelectronic package 400 does not a heat spreader, for applications where no heat spreader is needed or desired.

A step 370 of method 300 is to attach a passive component to the carrier such that the passive component is at least partially encapsulated by the encapsulation material along with the die. As an example, the passive component can be similar to passive component 260 that is shown in FIG. 2. As another example, the passive component can be similar to a passive component 960 that is first shown in FIG. 9. In one embodiment, FIG. 9 depicts microelectronic package 400 as it may appear following the performance of step 370. As an example, passive component 960 may be attached to heat spreader 970 with an adhesive (not shown) that may be similar to the adhesive in adhesive layer 120.

If, as in the illustrated embodiment, multiple dies have been processed simultaneously, step 370 may be followed by a process that singulates these multiple-die panels into individual units. The parts can then proceed through the appropriate backend processing steps to make them wither ball grid array (BGA), land grid array (LGA), or pin grid array (PGA) components.

FIG. 10 is a flowchart illustrating a method 1000 of forming a microelectronic package according to an embodiment of the invention. A step 1010 of method 1000 is to provide a heat spreader. As an example, the heat spreader can be similar to carrier 110 that is shown in FIG. 1. As another example, the heat spreader can be similar to a heat spreader 1110 that is first shown in FIG. 11, which is a cross-sectional view of a microelectronic package 1100 at a particular point in a manufacturing process according to an embodiment of the invention. In one embodiment, FIG. 11 depicts microelectronic package 1100 as it may appear following the performance of step 1010. As illustrated in FIG. 11, heat spreader 1110 has a surface 1111 and an opposing surface 1112.

A step 1020 of method 1000 is to attach a die to the heat spreader. As an example, the die can be similar to die 130 that is shown in FIG. 1. As another example, the die can be similar to a die 1230 that is first shown in FIG. 12, which is a cross-sectional view of a microelectronic package 1100 at a particular point in a manufacturing process according to an embodiment of the invention. In one embodiment, FIG. 12 depicts microelectronic package 1100 as it may appear following the performance of step 1020. FIG. 12 also depicts a die 1231, which may be similar to die 1230, thus illustrating that two (or more than two) dies can be processed simultaneously in a single package. These may later be singulated in order to increase manufacturing throughput. In a different embodiment, dies may be processed one at a time.

In one embodiment, step 1020 comprises applying a TIM to at least one of the die and the heat spreader and then bringing the die and the heat spreader into physical contact with each other such that an adhesive bond is formed between the die and the heat spreader. In other embodiments, step 1020 is accomplished in some other manner, such as by using a heat-cured adhesive, a solder material, or the like. As an example, the TIM can be similar to a TIM 1220 that is shown in FIG. 12 as being located, and creating an adhesive bond, between heat spreader 1110 and die 1230.

In a particular embodiment, TIM 1220 is a TIM preform. In the same or another embodiment, TIM 1220 is a thin TIM which, when combined with a thinned die of the type mentioned above, forms part of a thin die/thin TIM (TDTT) package environment. As illustrated in FIG. 12, microelectronic package 1100 further comprises a TIM 1221, which can be similar to TIM 1220, located, and creating an adhesive bond, between heat spreader 1110 and die 1231.

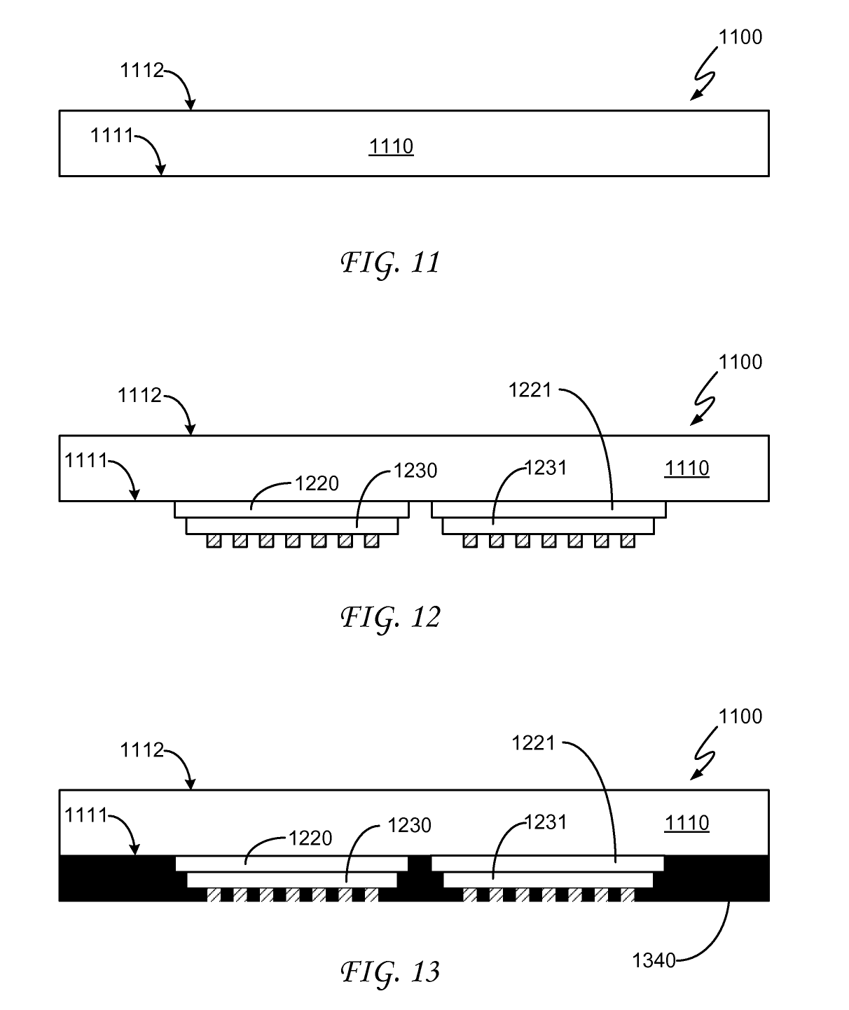

A step 1030 of method 1000 is to encapsulate at least a portion of the die with an encapsulation material. As an example, the encapsulation material can be similar to encapsulation material 140 that is shown in FIG. 1. As another example, the encapsulation material can be similar to an encapsulation material 1340 that is first shown in FIG. 13, which is a cross-sectional view of a microelectronic package 1100 at a particular point in a manufacturing process according to an embodiment of the invention. In one embodiment, FIG. 13 depicts microelectronic package 1100 as it may appear following the performance of step 1030. In one embodiment, step 1030 comprises applying the encapsulation material using one of a transfer molding process, a compression molding process, an injection molding process, and the like. One or more of these and other molding processes may contribute to lowered costs and increased throughput for microelectronic package 1100 (as well as other microelectronic packages according to the invention).

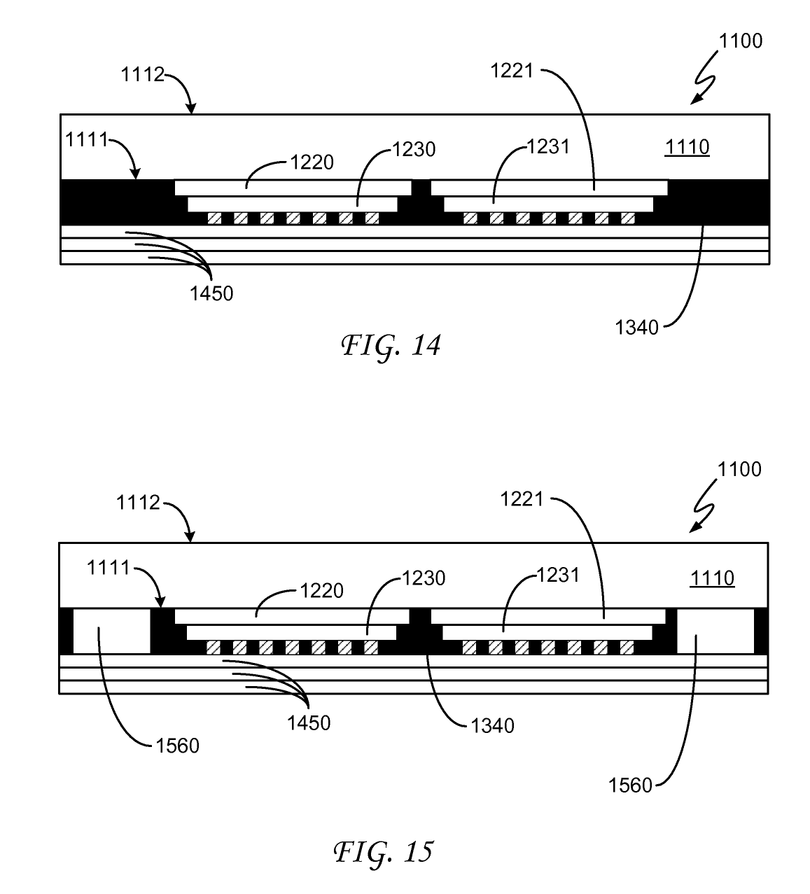

A step 1040 of method 1000 is to form at least one a build-up layer adjacent to the encapsulation material. As an example, the build-up layer can be similar to build-up layer 150 that is shown in FIG. 1. As another example, the build-up layer can be similar to a build-up layer 1450 that is first shown in FIG. 14, which is a cross-sectional view of a microelectronic package 1100 at a particular point in a manufacturing process according to an embodiment of the invention. In one embodiment, FIG. 14 depicts microelectronic package 1100 as it may appear following the performance of step 1040.

In one embodiment, step 1040 comprises patterning the build-up layer using a semi-additive patterning process, a laser projection patterning (LPP) process, a plasma etching process, a liquid resist process, a sputtering process, or another advanced fine line patterning technique. More than one such process may be used, if desired. In the same or another embodiment, step 1040 comprises embedding an integrated thin-film capacitor in the microelectronic package.

A step 1050 of method 1000 is to attach a passive component to the heat spreader such that the passive component is at least partially encapsulated by the encapsulation material along with the die. As an example, the passive component can be similar to passive component 260 that is shown in FIG. 2. As another example, the passive component can be similar to a passive component 1560 that is first shown in FIG. 15, which is a cross-sectional view of a microelectronic package 1100 at a particular point in a manufacturing process according to an embodiment of the invention. In one embodiment, FIG. 15 depicts microelectronic package 1100 as it may appear following the performance of step 1050. As an example, passive component 1560 may be attached to heat spreader 1110 with an adhesive (not shown) that may be similar to the adhesive in adhesive layer 120.

If, as in the illustrated embodiment, multiple dies have been processed simultaneously, step 1050 may be followed by a process that singulates these multiple-die panels into individual units. The parts can then proceed through the appropriate backend processing steps to make them wither ball grid array (BGA), land grid array (LGA), or pin grid array (PGA) components.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a carrier having a first surface and an opposing second surface;
an adhesive layer at the first surface of the carrier;
a die attached to the first surface of the carrier by the adhesive layer;
an encapsulation material at the first surface of the carrier and at least partially surrounding the die and the adhesive layer; and
a build-up layer adjacent to the encapsulation material, wherein the die and the build-up layer are in direct physical contact with each other.

2. The microelectronic package of claim 1 wherein:
the carrier comprises a thermally conductive material.

3. The microelectronic package of claim 2 wherein:
the carrier comprises an electrically conducting material.

4. The microelectronic package of claim 3 wherein:
the carrier comprises a copper sheet.

5. The microelectronic package of claim 1 wherein:
the adhesive layer comprises a thermal interface material.

6. The microelectronic package of claim 5 wherein:
the thermal interface material comprises one of a thermal grease, an elastomer pad, a phase change material, a polymer gel, and a solder material.

7. The microelectronic package of claim 1 wherein:
the adhesive layer comprises a removable adhesive film.

8. The microelectronic package of claim 7 wherein:
the removable adhesive film covers substantially all of the first surface of the carrier.

9. The microelectronic package of claim 1 wherein:
the die is one of a plurality of dies attached to the first surface of the carrier by the adhesive layer.

10. The microelectronic package of claim 1 further comprising:
a passive component attached to the first surface of the carrier and at least partially surrounded by the encapsulation material.

11. The microelectronic package of claim 1 further comprising:
an integrated thin-film capacitor in the build-up layer.

12. A microelectronic package comprising:
a heat spreader having a first surface and a second surface, wherein the second surface is a top surface of the microelectronic package;
a die attached to the first surface of the heat spreader;
an encapsulation material at the first surface of the heat spreader, the encapsulation material at least partially surrounding the die; and
a build-up layer physically contacting the encapsulation material and physically and electrically contacting the die.

13. The microelectronic package of claim 12 further comprising:
a thermal interface material between the die and the first surface of the heat spreader.

14. The microelectronic package of claim 13 further comprising:
a passive component attached to the heat spreader and at least partially encapsulated by the encapsulation material.

15. The microelectronic package of claim 14 further comprising:
an integrated thin-film capacitor in the build-up layer.

16. A method of forming a microelectronic package, the method comprising:
providing a carrier;
attaching a die to the carrier;
encapsulating at least a portion of the die with an encapsulation material;
forming a build-up layer adjacent to the encapsulation material; and
removing the carrier.

17. The method of claim 16 wherein:
attaching the die to the carrier comprises:
applying an adhesive film to at least one of the die and the carrier; and
bringing the die and the carrier into physical contact with each other such that an adhesive bond is formed between the die and the carrier.

18. The method of claim 17 wherein:
removing the carrier comprises removing the adhesive bond between the die and the carrier.

19. The method of claim 18 wherein:
removing the adhesive bond comprises applying one of thermal radiation and ultraviolet radiation to the adhesive bond.

20. The method of claim 16 further comprising:
attaching a heat spreader to a surface of the die.

21. The method of claim 16 further comprising:
attaching a passive component to the carrier such that the passive component is at least partially encapsulated by the encapsulation material along with the die.

22. The method of claim 16 wherein:
forming a build-up layer comprises forming an integrated thin-film capacitor in the build-up layer.

23. A method of forming a microelectronic package, the method comprising:
providing a heat spreader;
attaching a die to the heat spreader;
encapsulating at least a portion of the die with an encapsulation material; and
forming a build-up layer adjacent to the encapsulation material.

24. The method of claim 23 wherein:
attaching the die to the heat spreader comprises applying a thermal interface material to at least one of the die and the heat spreader; and
bringing the die and the heat spreader into physical contact with each other such that an adhesive bond is formed between the die and the heat spreader.

25. The method of claim 24 wherein:
applying the thermal interface material comprises applying a thermal interface material preform.

26. The method of claim 24 further comprising:
attaching a passive component to the heat spreader such that the passive component is at least partially encapsulated by the encapsulation material along with the die.

27. The method of claim 23 wherein:
forming the build-up layer comprises embedding an integrated thin-film capacitor in the microelectronic package.

28. The method of claim 23 wherein:
encapsulating at least a portion of the die comprises applying the encapsulation material using one of a transfer molding process, a compression molding process, and an injection molding process.

29. The method of claim 23 wherein:
forming a build-up layer comprises patterning the build-up layer using at least one of a semi-additive patterning process, a laser projection patterning process, a plasma etching process, a liquid resist process, and a sputtering process.
